(19) United States
(12) Patent Application Publication
(10) Pub. No.: US 2002/0034111 A1
(43) Pub. Date: Mar. 21, 2002

(54) Digital switch

(76) Inventor: Cheng-wen Hsu, Zhanghua (TW)

Correspondence Address: RABIN & CHAMPAGNE, PC, 1101 14TH STREET, NW, SUITE 500, WASHINGTON, DC, 20005, US

(21) Appl. No.: 09/950,828

(22) Filed: Sep. 13, 2001

(30) Foreign Application Priority Data
Sep. 14, 2000 (TW) 89118880

(51) Int. Cl. G11C 7/00

(52) U.S. Cl. 365/201

(57) ABSTRACT

A digital switch whose mechanism includes: a button, a microprocessor and a memory unit is provided. When the power supply is connected, the microprocessor outputs a control signal signifying an on/off status according to the digital switch status stored in the memory unit. When the user presses the button, the microprocessor reads the content values of the memory unit, reverses and stores it, and then outputs the control signal signifying an on/off status accordingly. When the power supply is turned off, the content of the memory unit will not be erased, such that the on/off status stored will not be altered. When the power supply is resumed, the digital switch status will remain the same as what it was when the power was turned off. The invention has the advantages of saving hardware space and reducing costs.

### BACKGROUND OF THE INVENTION

1. Field of the Invention

The invention relates in general to a digital switch, and more particularly to a digital switch, which achieves the switch function using a button in conjunction with software control.

2. Description of the Related Art

With respect to conventional mechanical switches, two kinds of status are involved: the on status and the off status. Moreover, the mechanical switch has memory function, that is, if the mechanical switch was in the on status before the power supply was turned off, the mechanical switch will remain in the on status when the power supply is resumed next time. Similarly, if the mechanical switch was in the off status before the power supply was turned off, the mechanical switch will remain in the off status when the power supply is resumed next time.

In recent years, Liquid Crystal Display monitor (LCD monitor) has been widely used in personal computers for it has the advantages of low radiation, compactness and smallness. Conventionally, the LCD monitor used to be equipped with audio speakers, and the audio switch is disposed on the panel of the LCD monitor to allow the user to control the on/off status of the audio speakers in order to achieve the feature of multimedia. For instance, the audio speakers will be set in mute status when the audio switch of the LCD monitor is on, and in non-mute status when the audio switch of the LCD monitor is off. Furthermore, when the power of the personal computer is resumed, the mute status setting of the speakers will remain the same as what it was at the time when the power was turned off.

However, in terms of mechanical design, a conventional mechanical switch still consumes too much space within the LCD monitor, therefore a larger housing design is required for the corresponding LCD monitor. In order to reduce the size of LCD monitor, it is of great necessity to search for other switching mechanism that can achieve the same on/off function.

### SUMMARY OF THE INVENTION

It is therefore an object of the invention to provide a digital switch, which replaces the conventional mechanical switch by adopting a conventional button in conjunction with software control, such that the on/off status of the digital switch is not altered unless the button is pressed. Furthermore, the on/off status of the digital switch will not be altered when the power supply has been power on or power off. The digital switch according to the invention uses a button, being small in size and cheap in cost, particularly suitable for such LCD monitor, which needs a switch but is restricted to the mechanical size.

According to the object of the invention, a digital switch, which is used to output a control signal, is provided. The digital switch includes: a microprocessor, a button and a memory unit, wherein the button is used to output a pulse to the microprocessor while the memory unit is used to store the on/off status of the digital switch. The memory unit preserves original content values when the power supply is power off. When being pressed, the button will send out a pulse to the microprocessor. When receiving the pulse sent from the button, the microprocessor reverses the on/off status of the digital switch stored in the memory unit and outputs a control signal corresponding to the reversed on/off status of the digital switch.

It is another object of the invention to provide a digital switch used in a monitor display. The digital switch is used to output an either ‘0’ or ‘1’ control signal, which can be used as an on/off signal. The digital switch includes: a button, a memory unit and a microprocessor, wherein the button is installed on the display panel for the user to operate while the memory unit is used to store the on/off status of the digital switch. The content value of the re-writable memory unit will not be erased when the power supply is off. The microprocessor, which reads the content values from the memory, acquires the status of the digital switch and outputs a control signal according to the status. Of which, the button sends a pulse to the microprocessor when the button is pressed by the user. After receiving the pulse, the microprocessor reverses the on/off status of the digital switch stored in the memory unit and outputs a control signal according to the reversed on/off status of the digital switch.

It is another object of the invention to provide a control method for a digital switch. The digital switch includes: a button, a memory unit and a microprocessor, wherein the button is installed on the display panel for the user to operate while the memory unit is used to store the on/off status of the digital switch. The control method includes the following steps:

(a) The microprocessor reads the status of a digital switch stored in a memory unit.

(b) The microprocessor outputs a control signal according to the digital switch status stored in the memory unit.

(c) Decision: if the pulse sent by the button has been received by the microprocessor, then go to (d); otherwise, go to (f).

(d) The microprocessor reverses the status of the digital switch.

(e) The microprocessor outputs a control signal according to the reversed digital switch status recorded in the memory unit; repeat (c).

(f) The microprocessor outputs a control signal according to the digital switch status recorded in the memory unit; repeat (c).

### BRIEF DESCRIPTION OF THE DRAWINGS

Other objects, features, and advantages of the invention will become apparent from the following detailed description of the preferred but non-limiting embodiments. The description is made with reference to the accompanying drawings in which:

FIG. 1 shows a structural block diagram of a digital switch according to a preferred embodiment of the invention; and

FIG. 2 shows a control flowchart of the digital switch in FIG. 1.

### DESCRIPTION OF THE PREFERRED EMBODIMENT

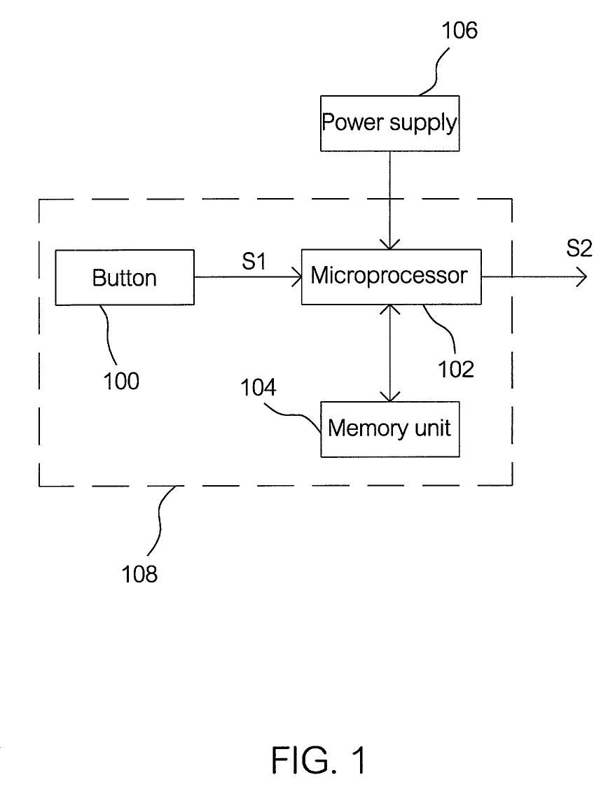

Referring to FIG. 1, a structural block diagram of a digital switch according to a preferred embodiment of the invention. The digital switch 108 can be used in a LCD monitor, which is linked to a personal computer, to control the mute setting of the audio speakers installed within the LCD monitor. The digital switch 108 includes a button 100, a microprocessor 102 and a non-volatile memory unit 104. The digital switch 108, which outputs the control signal S2 of either ‘0’ or ‘1’ corresponding to the mute and non-mute status respectively, controls the mute setting of the audio speakers. In addition, a power supply 106 provides the digital switch 108 with necessary power.

In relation to the digital switch 108, the button 100 is installed on the panel of the LCD monitor for the user to operate. When the user presses the button 100 once, the button 100 will output a pulse S1 to the microprocessor 102. The non-volatile memory unit 104 is used to store the status of the digital switch 108. For instance, when the content value of the memory unit 104 is ‘1’, it signifies the on status of the digital switch 108; when the content value of the memory unit 104 is ‘0’, it signifies the off status of the digital switch 108. Of which, the memory unit 104 is a non-volatile re-writable memory, whose stored contents will not be erased when the power supply 106 is off, can be used over and over again, such as a flash memory or a Electrically Erasable Programmable Read Only Memory (EEPROM). In other words, the non-volatile memory unit 104 stores and outputs the content value which can be either “1” or “0”. The microprocessor 102 is electrically connected with the memory unit 104 for receiving the content value. The microprocessor 102 outputs the first control signal “1” when the content value received is “1”, and outputs the second control signal “0” when the content value received is “0”. When the button 100 sends the microprocessor 102 a pulse, the microprocessor 102 changes the content value stored in the memory unit 104 from the “1” to “0” or from “0” to “1”, and the then the output control signal is also changed accordingly.

When the power supply 106 is turned on, the microprocessor 102 will read the content values of the memory unit 104 to acquire the status of the digital switch 108. Then the microprocessor 102 will output a control signal S2 according to the status of the digital switch 108, i.e., the control signal S2 is “1” when the status of the content value of the memory unit 104 is “1”. When the user presses the button 100 once, the button 100 will output a pulse S1 to the microprocessor 102. After receiving the pulse S1, the microprocessor 102 will reverse the status of the digital switch 108 stored in the memory unit 104 and output a control signal S2 according to the reversed status of the digital switch 108, i.e., the control signal S2 is reversed to “0” when the status of the content value of the memory unit 104 is reversed to “0”.

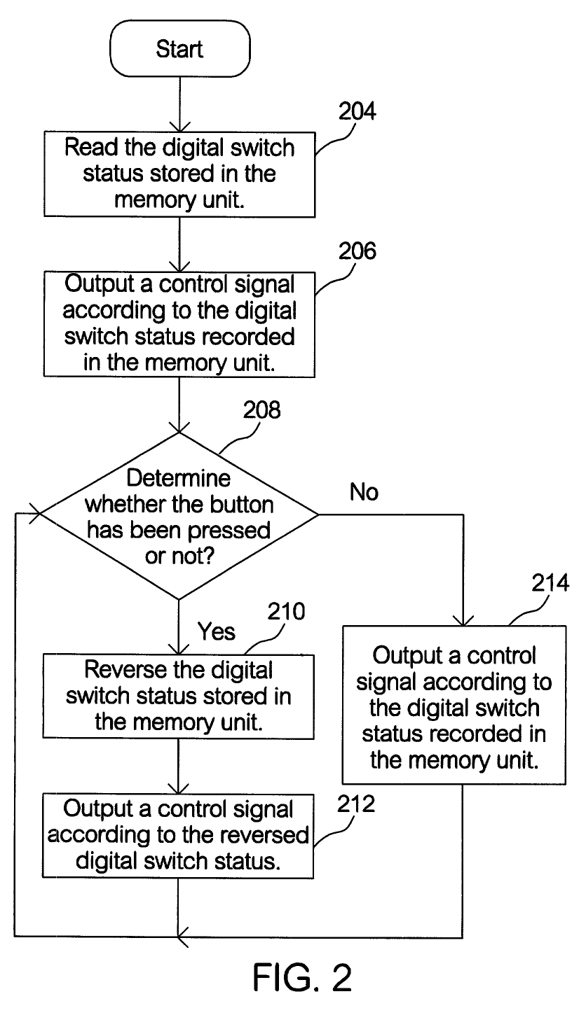

In order to make the control process of the above-mentioned digital switch easier to understand, please refer to FIG. 2, a control flowchart according to the digital switch in FIG. 1. Please refer to FIG. 1 as well. The step 204 is started when the power supply 106 is turned on: the microprocessor 102 reads the status of the digital switch 108 stored in the non-volatile memory unit 104.

Following that, the step 206 is performed: according to the status of the digital switch 108 stored in the non-volatile memory unit 104, the microprocessor 102 outputs a control signal S2 to complete the initialization following the starting of the power supply 106.

Next, go to the step 208: the microprocessor 102 determines whether the button 100 has been pressed or not. If the user would like to change the setting of mute status, he or she just needs to press the button 100 once. Then the button 100 will send the pulse S1 to the microprocessor 102 accordingly. Therefore, in the step 208, the microprocessor 102 determines whether the button 100 has been pressed or not according to whether the pulse S1 has been received or not. If yes, go to the step 210; otherwise, go to the step 214.

In the step 210, the microprocessor 102 reverses the status of the digital switch 108 stored in the non-volatile memory unit 104. That is, the microprocessor 102 reads the memory unit 104 first in order to acquire the original status of the digital switch 108, then reverses the status of the digital switch 108 and stores the reversed status in the memory unit 104.

Following that, the step 212 is performed: the microprocessor 102 outputs a control signal S2 according to the reversed status of the digital switch 108. After that, the process is returned to the step 208 waiting for the user's further pressing on the button 100.

In the step 214, the microprocessor 102 outputs a control signal S2 according to the status of the digital switch 108 stored in the non-volatile memory unit 104. After that, the process is returned to the step 208 waiting for the user's further pressing on the button 100.

For example, the content value of the memory unit 104 and the control signal S2 are assumed to be ‘1’ signifying the “on” status of the digital switch 108, so the audio speaker is set to be in the mute status. When the user presses the button 100 once, the microprocessor 102 receives the pulse S1 from the button 100 and reverses the content value of the memory unit 104 as ‘0’ signifying the off status of the digital switch 108. Correspondingly, the audio speaker will be set in the non-mute status.

Furthermore, since the non-volatile memory unit 104 used in the invention will not lose its stored contents when the power is off, the digital switch according to the invention has memory function as a conventional mechanical switch has. That is to say, if the status of the digital switch is on before the power supply 106 is turned off, the digital switch will remain in the on status when the power supply is activated again. Similarly, if the status of the digital switch is off before the power supply is turned off, the digital switch will remain in the off status when its power is resumed next time.

The microprocessor 102 used in the digital switch according to the invention can be the same microprocessor 102 originally installed in the LCD monitor for controlling the OSD (on screen display) menu, or the VESA power saving mechanism. In order to achieve the required functions in the invention, it needs only to slightly amend the original firmware process flow of the original microprocessor of the LCD monitor. As for the memory unit 104, it also can use the same memory used in the original LCD monitor. Therefore, it does not require extra microprocessor and memory hardware to implement this digital switch. The microprocessor will be able to output a control signal of ‘0’ and ‘1’, which is equivalent to a switch control, according to the user's pressing of the button to do the mute setting of a audio speaker, if the digital switch 108 according to the invention can have a button installed on the LCD monitor panel and have the software control of the microprocessor 102 adjusted. Generally speaking, a button costs much lower and occupies much smaller space than a switch would do. Therefore, the invention particularly fits such an apparatus, which needs a small switch due to its mechanical restraint. Additionally, the invention does not need to be limited to mute setting: the invention can be applied to whatever device which needs a switch function.

The digital switch according to the invention disclosed in the foregoing preferred embodiments has the following advantages: it occupies smaller space than a conventional mechanical switch does; its cost is low; its design is simple, only an extra button is needed to achieve the switch function; it is particularly suitable to a display, which needs a switch but is restricted by the size of mechanism.

While the invention has been described by way of example and in terms of the preferred embodiment, it is to be understood that the invention is not limited to the disclosed embodiment. To the contrary, it is intended to cover various modifications and similar arrangements and procedures, and the scope of the appended claims therefore should be accorded the broadest interpretation so as to encompass all such modifications and similar arrangements and procedures.

What is claimed is:

1. A digital switch for selectively outputting a first control signal and a second control signal, the digital switch comprising:
a non-volatile memory unit for storing and outputting a content value, the content value being one of a first status value and a second status value;
a microprocessor electrically connected with the memory unit for receiving the content value, the microprocessor outputting the first control signal when the content value being the first status value, and outputting the second control signal when the content value being the second status value; and
a button electrically connected with the microprocessor, and the button outputting a pulse to the microprocessor when the button being pressed;
wherein when receiving the pulse sent from the button, the microprocessor changing the content value stored in the memory unit from the first status value to the second status value.

2. A digital switch according to claim 1, wherein the non-volatile memory unit is a flash memory.

3. A digital switch to claim 1, wherein the non-volatile memory unit is an Electrically Erasable Programmable Read Only Memory (EEPROM).

4. A digital switch according to claim 1, wherein the digital switch is applied in a Liquid Crystal Display monitor (LCD monitor).

5. A digital switch according to claim 4, wherein the button is installed on the panel of the LCD monitor.

6. A digital switch used in a display to output a control signal of either ‘0’ or ‘1’ served as an on/off signal, comprising:
a button installed on the display panel for the user to operate;
a memory unit, which is used to store the on/off status of the digital switch and whose stored contents will not be erased when the power is off, is a re-writable memory which can be used over and over again; and
a microprocessor, which reads the content values from the memory, acquires the digital switch status and outputs a control signal according to the status;
wherein the button sends a pulse to the microprocessor when the button is pressed by the user; after receiving the pulse, the microprocessor reverses the on/off status of the digital switch stored in the memory unit and outputs a control signal according to the reversed on/off status of the digital switch.

7. A digital switch according to claim 6, wherein the digital switch is in the on status when the content value of the memory unit is the first value while the digital switch is in the off status when the content value of the memory unit is the second value.

8. A digital switch according to claim 6, wherein the memory unit is a flash memory.

9. A digital switch according to claim 6, wherein the memory unit is an Electrically Erasable Programmable Read Only Memory (EEPROM).

10. A control method for a digital switch, wherein the digital switch compromises a button and a non-volatile memory unit: the button is installed on the display panel for the user to operate, the method compromising the following steps:
a. The microprocessor reads the status of a digital switch stored in a memory unit,
b. The microprocessor outputs the control signal according to the digital switch status stored in the memory unit,
c. Decision: if the pulse sent by the button has been received by the microprocessor, then go to d; otherwise, go to f,
d. The microprocessor reverses the digital switch status,
e. The microprocessor outputs a control signal according to the reversed digital switch status recorded in the memory unit, repeat c; and
f. The microprocessor outputs a control signal according to the digital switch status recorded in the memory unit; repeat C.

11. A control method according to claim 11, wherein the digital switch is in the on status when the content value of the memory unit is the first value while the digital switch is in the off status when the content value of the memory unit is the second value.

12. A control method according to claim 11, wherein the memory unit is a flash memory.

13. A control method according to claim 11, wherein the memory unit is an Electrically Erasable Programmable Read Only Memory (EEPROM).

14. A control method according to claim 11, wherein step d further compromises the following steps:
d1. The microprocessor reads the content values of the memory unit and acquires the digital switch status;
d2. Reverse the digital switch status; and
d3. Store the reversed digital switch status in the memory unit.
